(19) United States
(12) Patent Application Publication
(10) Pub. No.: US 2018/0145211 A1
(43) Pub. Date: May 24, 2018

(54) OPTOELECTRONIC ARRANGEMENT AND DEPTH MEASURING SYSTEM

(71) Applicant: OSRAM Opto Semiconductors GmbH, Regensburg (DE)

(72) Inventors: Hubert Halbritter, Dietfurt-Toeging (DE); Markus Arzberger, Sunnyvale, CA (US); Alexander Linkov, Regensburg (DE)

(21) Appl. No.: 15/577,626

(22) PCT Filed: May 27, 2016
(86) PCT No.: PCT/EP2016/062044

§ 371 Date: Nov. 28, 2017

(30) Foreign Application Priority Data
May 28, 2015 (DE) 10 2015 108 413.9
Dec. 22, 2015 (DE) 10 2015 122 627.8

(51) Int. Cl. H01L 33/08; H01L 33/58; G06T 7/521

(52) U.S. Cl. CPC H01L 33/08; H01L 33/105; G06T 7/521; H01L 33/58

(57) ABSTRACT

An optoelectronic arrangement that produces a light pattern includes a light-emitting diode chip configured to emit electromagnetic radiation on its upper side and forming a first two-dimensional pattern on the upper side of the light-emitting diode chip, and an optically imaging element configured to project electromagnetic radiation emitted by the light-emitting diode chip into an environment of the optoelectronic arrangement.

### TECHNICAL FIELD

This disclosure relates to an optoelectronic arrangement and a depth measuring system.

### BACKGROUND

Optoelectronic arrangements that produce a light pattern, for example, a pattern of light points are known and used, for example, in depth measuring systems to obtain depth information with the aid of back-scattered light of the light pattern. Known optoelectronic arrangements that produce light patterns may, for example, have laser light sources and diffractive optical elements or shadowing aperture structures.

There is a need to provide an improved optoelectronic arrangement that produces a light pattern and a depth measuring system.

### SUMMARY

We provide an optoelectronic arrangement that produces a light pattern including a light-emitting diode chip configured to emit electromagnetic radiation on its upper side and forming a first two-dimensional pattern on the upper side of the light-emitting diode chip, and an optically imaging element configured to project electromagnetic radiation emitted by the light-emitting diode chip into an environment of the optoelectronic arrangement.

We also provide a depth measuring system including the optoelectronic arrangement that produces a light pattern including a light-emitting diode chip configured to emit electromagnetic radiation on its upper side and forming a first two-dimensional pattern on the upper side of the light-emitting diode chip, and an optically imaging element configured to project electromagnetic radiation emitted by the light-emitting diode chip into an environment of the optoelectronic arrangement.

### BRIEF DESCRIPTION OF THE DRAWINGS

FIG. 1 shows a first optoelectronic arrangement.

FIG. 2 shows a plan view of an upper side of a light-emitting diode chip of the first optoelectronic arrangement.

FIG. 3 shows a second optoelectronic arrangement.

FIG. 4 shows a third optoelectronic arrangement.

FIG. 5 shows a depth measuring system.

FIG. 6 shows a fourth optoelectronic arrangement.

FIG. 7 shows a schematic equivalent circuit diagram of the light-emitting diode chip of the fourth optoelectronic arrangement.

FIG. 8 shows a fifth optoelectronic arrangement.

FIG. 9 shows a sixth optoelectronic arrangement.

FIG. 10 shows a seventh optoelectronic arrangement.

FIG. 11 shows an eighth optoelectronic arrangement.

### LIST OF REFERENCES

optoelectronic arrangement 10
optoelectronic arrangement 11
optoelectronic arrangement 12
optoelectronic arrangement 13
optoelectronic arrangement 14
optoelectronic arrangement 15
optoelectronic arrangement 16
optoelectronic arrangement 17
depth measuring system 20
detector 30
light-emitting diode chip 100
first diode structure 101
second diode structure 102
third diode structure 103
upper side 110
radiation-emitting section 111
radiation-nonemitting section 112
straight line 113
first section 114
second section 115
third section 116
layer sequence 120
optical resonator 121
pn junction 130
rear-side contact 140
first upper-side side contact 141
second upper-side side contact 142
third upper-side side contact 143
electromagnetic radiation 200
two-dimensional pattern 210
second two-dimensional pattern 220
third two-dimensional pattern 230
fundamental mode 240
optically imaging element 300
environment 310
aperture element 400
opening 410
diameter 411
focusing element 500
optical element 600
angle range 610

### DETAILED DESCRIPTION

Our optoelectronic arrangement that produces a light pattern comprises a light-emitting diode chip configured to emit electromagnetic radiation on its upper side, and forms a first two-dimensional pattern on the upper side of the light-emitting diode chip. The optoelectronic arrangement furthermore comprises an optically imaging element configured to project electromagnetic radiation emitted by the light-emitting diode chip into an environment of the optoelectronic arrangement.

Advantageously, a light-emitting diode chip is used as the light source in this optoelectronic arrangement so that the optoelectronic arrangement can be produced economically, scaled with little outlay, and handled easily. In particular, owing to the absence of a laser light source, no eye safety measures have to be taken in this optoelectronic arrangement. The optoelectronic arrangement advantageously has a simple structure with a small number of individual component parts so that the optoelectronic arrangement can have compact external dimensions.

The first pattern may be configured such that at least two radiation-emitting sections and two radiation-nonemitting sections alternate along a straight line arranged on the upper side of the light-emitting diode chip. This advantageously ensures that the light pattern that can be produced by the optoelectronic arrangement is sufficiently complex for the light pattern that can be produced by the optoelectronic arrangement to be used in a depth measuring system to determine depth information.

The first pattern may be a two-dimensional point pattern. The point pattern may in this case be a regular or irregular point pattern. Two-dimensional point patterns have proven to be highly suitable for use in systems for depth measurement.

The first pattern may be a strip pattern. Strip patterns are also suitable for use in systems for depth measurement, and advantageously allow particularly simple evaluation.

The light-emitting diode chip may be configured to emit electromagnetic radiation with a wavelength in the infrared spectral range. The light pattern that can be produced by the optoelectronic arrangement is thus advantageously not visible and is, therefore, not perceived as perturbing by a user.

The light-emitting diode chip may have an epitaxially grown layer sequence. In this case, a region of the layer sequence is structured according to the first pattern in the lateral direction. The effect advantageously achieved by this is that the light-emitting diode chip produces electromagnetic radiation only in those regions in which electromagnetic radiation is intended to be emitted on the upper side of the light-emitting diode chip. It is therefore not necessary to shadow electromagnetic radiation in those regions on the upper side of the light-emitting diode chip that are not intended to emit electromagnetic radiation. The optoelectronic arrangement can therefore advantageously have a high efficiency.

The layer sequence may have a pn junction, which is laterally structured. The effect advantageously achieved by this is that electromagnetic radiation would be produced in the light-emitting diode chip of the optoelectronic arrangement only in the regions in which electromagnetic radiation is intended to be emitted on the upper side of the light-emitting diode chip.

The optically imaging element may comprise an optical lens. The optical lens in this case may, for example, be configured as a diverging lens. Advantageously, the optically imaging element is therefore suitable for projecting electromagnetic radiation emitted by the light-emitting diode of the optoelectronic arrangement into an environment of the optoelectronic arrangement.

An aperture element having openings over radiation-emitting sections of the upper side may be arranged over the upper side of the light-emitting diode chip. Advantageously, at least partial parallelization of the electromagnetic radiation emitted by the light-emitting diode chip can be achieved by the aperture element. Electromagnetic radiation emitted at an angle deviating strongly from the normal is in this case absorbed in the openings of the aperture element.

At least one of the openings may be dimensioned to be so narrow that only a fundamental mode of the electromagnetic radiation can pass through the opening. The opening in this case may, for example, have a diameter of less than 10 μm. The fundamental mode advantageously has a narrow emission angle so that the emitted electromagnetic radiation is strongly directed and has a high radiation intensity in a direction perpendicular to the upper side of the light-emitting diode chip. This advantageously allows efficient coupling into the optically imaging element of the optoelectronic arrangement. Furthermore, the light pattern produced by the optoelectronic arrangement therefore has a high contrast.

A focusing element intended to at least partially parallelize electromagnetic radiation emitted on the radiation-emitting section may be arranged over at least one radiation-emitting section of the upper side of the light-emitting diode chip. Advantageously, the focusing element may achieve the partial parallelization of the electromagnetic radiation by refraction and deflection of the electromagnetic radiation so that losses due to absorption can be reduced. In this way, the optoelectronic arrangement can have a particularly high efficiency.

The focusing element may comprise a microprism. For example, focusing elements configured as a microprism array may be arranged over the radiation-emitting sections of the upper side of the light-emitting diode chip. The focusing element can therefore advantageously be produced simply and economically.

The light-emitting diode chip may be configured to emit on its upper side electromagnetic radiation forming a second two-dimensional pattern, different from the first pattern, on the upper side of the light-emitting diode chip. In this example, the light-emitting diode chip is therefore configured to produce at least two different light patterns. These two light patterns may, for example, be produced sequentially after one another. Advantageously, the optoelectronic arrangement is therefore particularly highly suitable for use in a system for depth measurement, and allows depth measurement with particularly high accuracy.

The first pattern and the second pattern may be configured such that the radiation-emitting sections of the upper side of the light-emitting diode chip that form the first pattern, and the radiation-emitting sections of the upper side of the light-emitting diode chip that form the second pattern, are disjointed. This means that the radiation-emitting sections of the upper side of the light-emitting diode chip that form the first pattern, and the radiation-emitting sections of the upper side of the light-emitting diode chip that form the second pattern do not overlap. Advantageously, the first pattern and the second pattern can therefore be produced particularly simply with only one light-emitting diode chip.

The light-emitting diode chip may have a multiplicity of electrical contacts. In this case, the light-emitting diode chip is configured to emit the first pattern or the second pattern depending on which electrical contact receives electrical current. The light-emitting diode chip of the optoelectronic arrangement may thus have at least two integrated diode structures. In this way, the light-emitting diode chip can advantageously be driven particularly simply.

The light-emitting diode chip may be configured to emit on its upper side electromagnetic radiation that forms a third two-dimensional pattern, different from the first pattern and the second pattern, on the upper side of the light-emitting diode chip. In this example, the optoelectronic arrangement is therefore advantageously suitable for producing at least three different patterns which may, for example, be produced sequentially after one another. When the optoelectronic arrangement is used in a system for depth measurement, depth measurement with particularly high accuracy is therefore advantageously made possible.

The light-emitting diode chip may be configured with an optical resonator or as a superluminescent diode. Advantageously, the light-emitting diode chip can therefore permit production of electromagnetic radiation with a wavelength in a narrow spectral range, which, when the optoelectronic arrangement is used in a system for depth measurement, makes it possible to use a filter with a narrow transmission spectrum on the detector side so that a low susceptibility to interference and a high signal quality can be obtained. Another advantage may be that a light-emitting diode chip configured with an optical resonator or as a superluminescent diode can have a narrow-angled emission characteristic so that the light pattern that can be produced by the optoelectronic arrangement can have a high contrast and a high intensity.

An optical element that transmits only electromagnetic radiation emitted in a fixed angle range about a direction perpendicular to the upper side of the light-emitting diode chip may be arranged over at least one radiation-emitting section of the upper side of the light-emitting diode chip. Advantageously, the electromagnetic radiation emitted by the optoelectronic arrangement then has a high parallelism and a low divergence so that the light pattern that can be produced by the optoelectronic arrangement can have a high contrast. Electromagnetic radiation not transmitted by the optical element may be reflected to the light-emitting diode chip and thereby recycled. For example, electromagnetic radiation reflected at the optical element may be reabsorbed in the light-emitting diode chip. It is likewise possible for electromagnetic radiation reflected at the optical element to be reflected again at the light-emitting diode chip and, in this case, emitted in a direction essentially perpendicular to the upper side of the light-emitting diode chip.

The optical element may be configured as a photonic crystal. The optical element then advantageously transmits only electromagnetic radiation emitted in a fixed angle range about a direction perpendicular to the upper side of the light-emitting diode chip.

A depth measuring system comprises an optoelectronic arrangement of the type mentioned above. The depth measuring system may, for example, be intended to determine distances of persons and/or objects arranged in a target region. The depth measuring system may, for example, also be suitable for determining distances of individual body parts of one or more persons from the optoelectronic arrangement of the depth measuring system. In this case, the depth measuring system may, for example, obtain the depth information with the aid of reflected light of the light pattern that can be produced by the optoelectronic arrangement of the depth measuring system.

The above-described properties, features and advantages, as well as the way in which they are achieved, will become more clearly and readily comprehensible in conjunction with the following description of the examples, which will be explained in more detail in connection with the drawings that, respectively, show schematic representations.

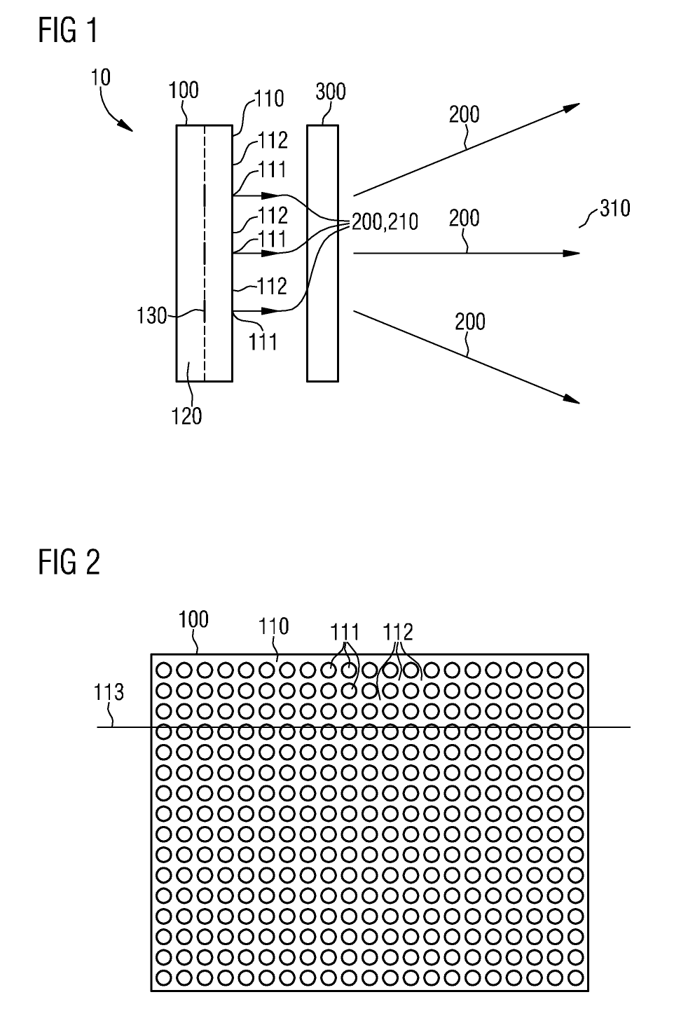

FIG. 1 shows a highly schematized sectional side view of an optoelectronic arrangement 10. The optoelectronic arrangement 10 is intended to produce and emit a light pattern.

The optoelectronic arrangement 10 comprises a light-emitting diode chip 100. The light-emitting diode chip 100 may also be referred to as an LED chip. The light-emitting diode chip 100 is configured to emit electromagnetic radiation 200. The electromagnetic radiation 200 that can be emitted by the light-emitting diode chip 100 may have a wavelength in the visible spectral range or a wavelength in a non-visible spectral range, for example, a wavelength in the infrared spectral range. In both cases, the electromagnetic radiation 200 that can be emitted by the light-emitting diode chip 100 may also be referred to as light.

The light-emitting diode chip 100 has an upper side 110. The upper side 110 forms a radiation emission face of the light-emitting diode chip 100. The electromagnetic radiation 200 that can be emitted by the light-emitting diode chip 100 is emitted on the upper side 110 of the light-emitting diode chip 100.

FIG. 2 shows a schematic plan view of the upper side 110 of the light-emitting diode chip 100 of the optoelectronic arrangement 10. The electromagnetic radiation 200 that can be emitted by the light-emitting diode chip 100 is not emitted on the entire upper side 110 of the light-emitting diode chip 100. Rather, the upper side 110 of the light-emitting diode chip 100 has radiation-emitting sections 111 and radiation-nonemitting sections 112. During operation of the light-emitting diode chip 100, electromagnetic radiation 200 is emitted merely on the radiation-emitting sections 111 of the upper side 110 of the light-emitting diode chip 100.

The radiation-emitting sections 111 of the upper side 110 of the light-emitting diode chip 100 form a two-dimensional pattern. The electromagnetic radiation 200 emitted by the light-emitting diode chip 100 on the upper side 110 therefore also forms a two-dimensional pattern 210 on the upper side 110 of the light-emitting diode chip 100. The two-dimensional pattern 210 in this case is configured such that at least two radiation-emitting sections 111 and two radiation-nonemitting sections 112 alternate along a straight line 113 arranged on the upper side 110 of the light-emitting diode chip 100.

In the example shown in FIG. 2, the radiation-emitting sections 111 form a regular two-dimensional point pattern. The radiation-emitting sections 111 could however also form an irregular point pattern, a grid pattern or another pattern.

The light-emitting diode chip 100 has an epitaxially grown layer sequence 120. The layer sequence 120 comprises a pn junction 130. The electromagnetic radiation 200 is produced in the region of the pn junction 130 of the layer sequence 120 during operation of the light-emitting diode chip 100 of the optoelectronic arrangement 10.

The pn junction 130 is structured in the lateral direction, i.e. parallel to the upper side 110 of the light-emitting diode chip 100, according to the two-dimensional pattern 210. The effect achieved by this is that, during operation of the light-emitting diode chip 100, electromagnetic radiation 200 is produced only in those lateral regions of the layer sequence 120 arranged below radiation-emitting sections 111 of the upper side 110 of the light-emitting diode chip 100 in a direction perpendicular to the upper side 110 of the light-emitting diode chip 100. No electromagnetic radiation 200 is produced below the radiation-nonemitting sections 112 of the upper side 110 of the light-emitting diode chip 100. The two-dimensional pattern 210 of the electromagnetic radiation 200 that can be emitted by the light-emitting diode chip 100 is therefore already formed during production of the electromagnetic radiation 200 in the layer sequence 120 of the light-emitting diode chip 100.

FIG. 1 shows that the optoelectronic arrangement 100 additionally comprises an optically imaging element 300. The optically imaging element 300 is intended to project the electromagnetic radiation 200 emitted by the light-emitting diode chip 100 of the optoelectronic arrangement 10 into an environment 310 of the optoelectronic arrangement 10. To this end, the optically imaging element 300 is arranged such that the electromagnetic radiation 200 emitted by the light-emitting diode chip 100 travels through the optically imaging element 300.

The optically imaging element 300 may, for example, comprise an optical lens. The optical lens may, for example, be configured as a diverging lens. The optically imaging element 300 may also comprise more than one optical component part, for example, a plurality of optical lenses arranged successively in the light path.

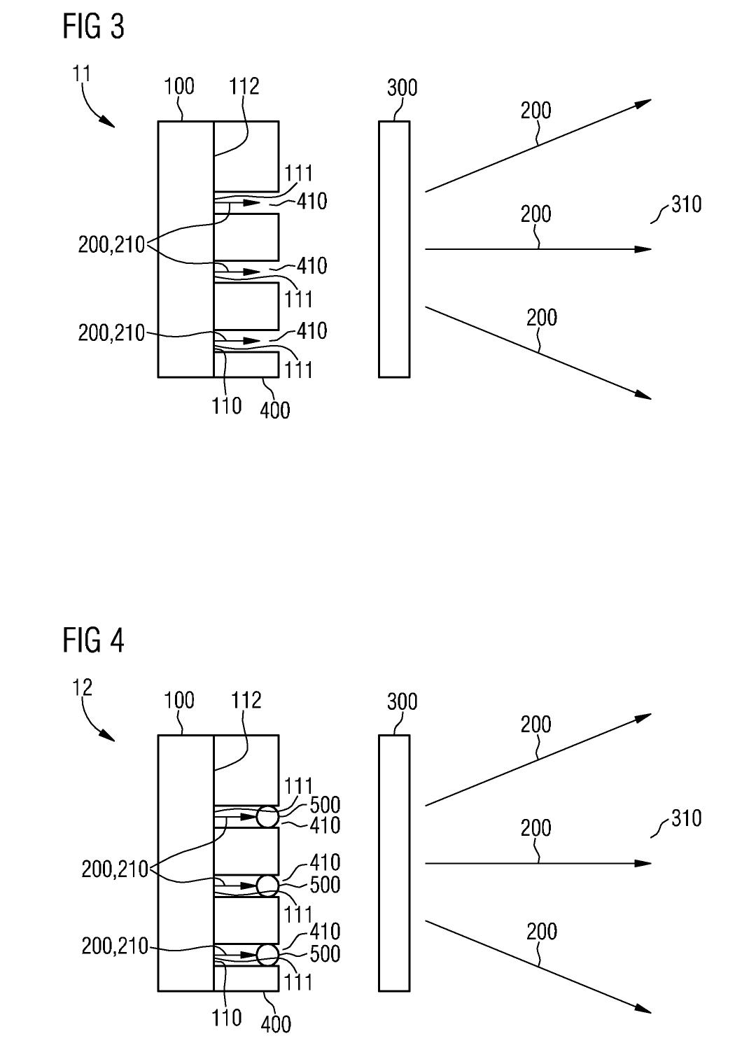

FIG. 3 shows a highly schematized sectional side view of an optoelectronic arrangement 11 according to a second example. The optoelectronic arrangement 11 has great similarities with the optoelectronic arrangement 10 of FIG. 1. Component parts of the optoelectronic arrangement 11 corresponding to component parts present in the optoelectronic arrangement 10 are provided with the same references in FIG. 3 as in FIG. 1. The following description concentrates on the differences between the optoelectronic arrangement 11 of FIG. 3 and the optoelectronic arrangement 10 of FIG. 1. In other regards, the description of the optoelectronic arrangement 10 is also applicable for the optoelectronic arrangement 11.

The optoelectronic arrangement 11 has an aperture element 400 arranged between the upper side 110 of the light-emitting diode chip 100 and the optically imaging element 300. The aperture element 400 may bear directly on the upper side 110 of the light-emitting diode chip 100. The aperture element 400 may also be referred to as an aperture element.

The aperture element 400 has openings 410. The sections of the aperture element 400 enclosing the openings 410 of the aperture element 400 are configured to be opaque. It is expedient for the sections of the aperture element 400 enclosing the openings 410 of the aperture element 400 to be configured to be nonreflective or only slightly reflective. The openings 410 of the aperture element 400 are aligned with the radiation-emitting sections 111 of the upper side 110 of the light-emitting diode chip 100. In this way, a part of the electromagnetic radiation 200 emitted on the radiation-emitting sections 111 of the upper side 110 of the light-emitting diode chip 100 can travel through the openings 410 of the aperture element 400 to the optically imaging element 300 of the optoelectronic arrangement 11.

However, only electromagnetic radiation emitted perpendicularly or almost perpendicularly to the upper side 110 of the light-emitting diode chip 100 can pass through the openings 410 of the aperture element 400. Electromagnetic radiation 200 emitted on the upper side 110 of the light-emitting diode chip 100 in a direction which has an angle, relative to a normal oriented perpendicularly to the upper side 110 of the light-emitting diode chip 100, which is greater than a geometrically fixed limit angle is absorbed at the aperture element 400 or the walls of the openings 410.

In this way, the electromagnetic radiation 200 emerging from the openings 410 of the aperture element 400 on the opposite side of the aperture element 400 from the optically imaging element 300 is essentially oriented perpendicularly to the upper side 110 of the light-emitting diode chip 100 and is therefore at least partially parallelized.

The partial parallelization of the electromagnetic radiation 200 due to the aperture element 400 may be used to reduce perturbing back-reflections of electromagnetic radiation 200 inside the optoelectronic arrangement 11 and to increase the quality, produced by the optically imaging element 300, of the projection of the two-dimensional pattern 210 of the electromagnetic radiation 200.

FIG. 4 shows a highly schematized sectional side view of an optoelectronic arrangement 12 according to a third example. The optoelectronic arrangement 12 has great similarities with the optoelectronic arrangement 11 represented in FIG. 3. Component parts of the optoelectronic arrangement 12 corresponding to component parts present in the optoelectronic arrangement 11 are provided with the same references in FIG. 4 as in FIG. 3. The following description concentrates on the differences between the optoelectronic arrangement 12 and the optoelectronic arrangement 11. In other regards, the description of the optoelectronic arrangement 10 of FIG. 1 and of the optoelectronic arrangement 11 of FIG. 3 is also applicable for the optoelectronic arrangement 12 of FIG. 4.

In addition to the aperture element 400, the optoelectronic arrangement 12 comprises a multiplicity of focusing elements 500. The focusing elements 500 are arranged over the radiation-emitting sections 111 of the upper side 110 of the light-emitting diode chip 100 in the openings 410 of the aperture element 400. The focusing elements 500 are intended to at least partially parallelize electromagnetic radiation 200 emitted on the radiation-emitting sections 111 of the upper side 110 of the light-emitting diode chip 100. In this way, a fraction of the electromagnetic radiation 200 absorbed at the walls of the openings 410 of the aperture element 400 can be reduced. In this way, the usable part of the electromagnetic radiation 200 emitted by the light-emitting diode chip 100 can be increased.

The focusing element 500 may, for example, comprise microprisms. In particular, the focusing elements 500 may, for example, be formed by a microprism array.

It is possible to configure the optoelectronic arrangement 12 with the focusing elements 500 but without the aperture element 400. In this case, the electromagnetic radiation 200 emitted by the light-emitting diode chip 100 is only partially parallelized by the focusing elements 500.

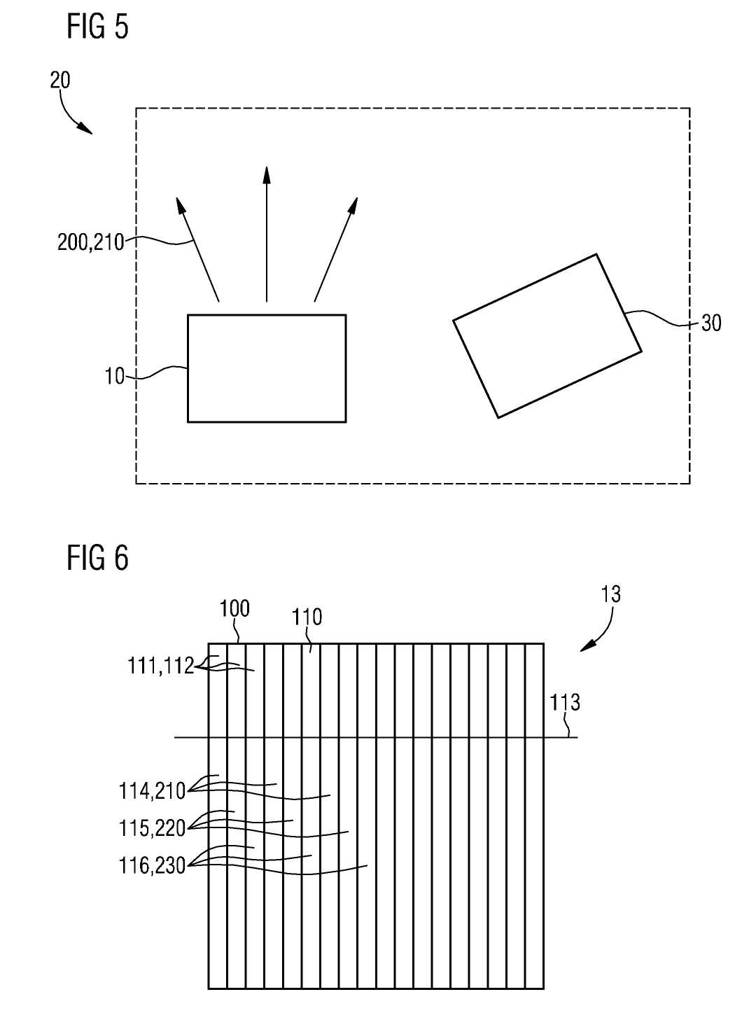

FIG. 5 shows a highly schematized representation of a depth measuring system 20. The depth measuring system 20 is intended to determine a spatial depth of objects and/or bodies arranged in a spatial region to be examined, i.e. a distance of these objects and/or bodies from the depth measuring system 20.

The depth measuring system 20 comprises the optoelectronic arrangement 10 of FIG. 1. Instead of the optoelectronic arrangement 10, however, the depth measuring system 20 can also comprise the optoelectronic arrangement 11 of FIG. 3 or the optoelectronic arrangement 12 of FIG. 4. The optoelectronic arrangement 10 is intended to emit a two-dimensional pattern 210 of electromagnetic radiation 200 into the spatial region to be examined.

The depth measuring system 20 furthermore comprises a detector 30. The detector 30 may, for example, be configured as a camera, in particular, for example, as a CCD camera.

The two-dimensional pattern 210 of electromagnetic radiation 200 emitted by the optoelectronic arrangement 10 of the depth measuring system 20 is at least partially reflected by the bodies and/or objects in the spatial region to be examined. The reflected electromagnetic radiation is detected by the detector 30 of the depth measuring system 20 and evaluated by the depth measuring system 20. The depth measuring system 20 can determine the spatial depth of the objects and/or bodies arranged in the spatial region to be examined from the pattern of the reflected radiation.

FIG. 6 shows a schematic plan view of the upper side 110 of the light-emitting diode chip 100 of an optoelectronic arrangement 13 according to a fourth example. The optoelectronic arrangement 13 has great similarities with the optoelectronic arrangement 10 of FIG. 1. Component parts of the optoelectronic arrangement 13 corresponding to component parts present in the optoelectronic arrangement 10 are provided with the same references in FIG. 6 as in FIG. 1. The following description concentrates on the differences between the optoelectronic arrangement 13 of FIG. 6 and the optoelectronic arrangement 10 of FIG. 1. In other regards, the description of the optoelectronic arrangement 10 is also applicable for the optoelectronic arrangement 13.

In the optoelectronic arrangement 13, the upper side 110 of the light-emitting diode chip 100 has strip-shaped first sections 114, strip-shaped second sections 115 and strip-shaped third sections 116. The strip-shaped sections 114, 115, 116 do not overlap one another, and are therefore disjointed. The strip-shaped sections 114, 115, 116 are arranged next to one another such that a first section 114, a second sections 115 and a third section 116 always follow one another along a straight line 113 oriented perpendicularly to the strip-shaped sections 114, 115, 116, on the upper side 110 of the light-emitting diode chip 100. These are in turn followed by a first section 114, a second sections 115 and a third section 116. This pattern may be repeated many times, for example, a few dozen times or a few hundred times

The light-emitting diode chip 100 of the optoelectronic arrangement 13 may be operated such that the first sections 114 of the upper side 110 of the light-emitting diode chip 100 form radiation-emitting sections 111, while the second sections 115 and the third sections 116 of the upper side 110 of the light-emitting diode chip 100 form radiation-nonemitting sections 112. The electromagnetic radiation 200 emitted on the first sections 114 of the upper side 110 of the light-emitting diode chip 100 then forms the two-dimensional pattern 210 on the upper side 110 of the light-emitting diode chip 100, which in this case is a strip pattern.

The light-emitting diode chip 100 of the optoelectronic arrangement 13 may, however, also be operated such that the second sections 115 of the upper side 110 of the light-emitting diode chip 100 form radiation-emitting sections 111, while the first sections 114 and the third sections 116 of the upper side 110 of the light-emitting diode chip 100 form radiation-nonemitting sections 112. The electromagnetic radiation 200 emitted on the radiation-emitting sections 111 of the upper side 110 of the light-emitting diode chip 100 then forms a second two-dimensional pattern 220 on the upper side 110 of the light-emitting diode chip 100. The second two-dimensional pattern 220 is likewise configured as a strip pattern, although it is laterally displaced, or phase-shifted, relative to the two-dimensional pattern 210.

The light-emitting diode chip 100 of the optoelectronic arrangement 13 may furthermore be operated such that the third sections 116 of the upper side 110 of the light-emitting diode chip 100 form radiation-emitting sections 111, while the first sections 114 and the second sections 115 of the upper side 110 of the light-emitting diode chip 100 form radiation-nonemitting sections 112. Electromagnetic radiation 200 emitted on the radiation-emitting sections 111 of the upper side 110 of the light-emitting diode chip 100 then forms a third two-dimensional pattern 230 on the upper side 110 of the light-emitting diode chip 100. The third two-dimensional pattern 230 is likewise configured as a strip pattern. The third two-dimensional pattern 230 is laterally displaced, or phase-shifted, relative to the two-dimensional pattern 210 and the second two-dimensional pattern 220.

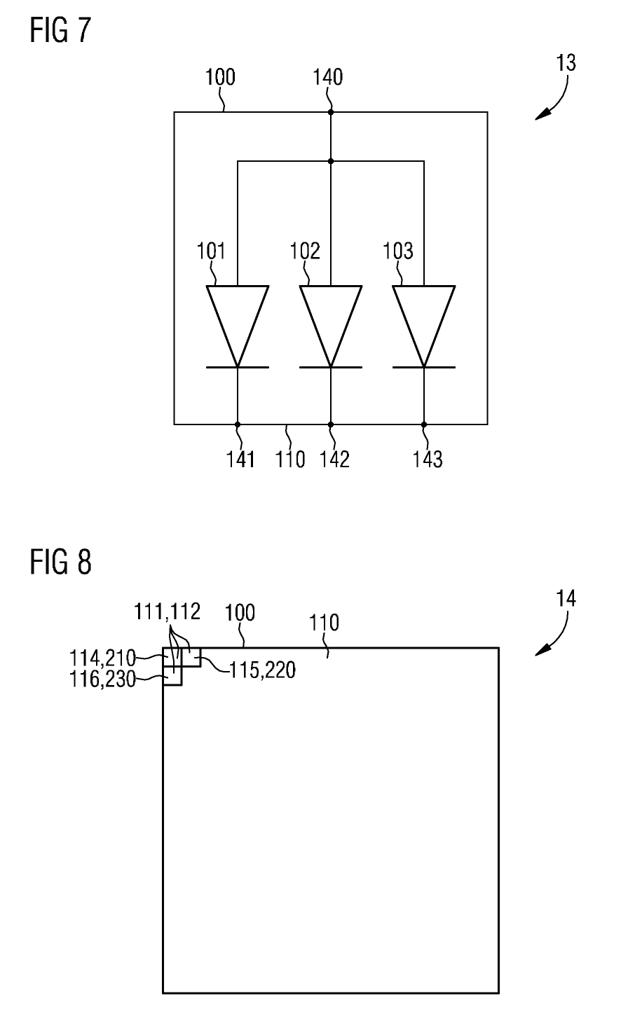

FIG. 7 shows a highly schematized equivalent circuit diagram of the light-emitting diode chip 100 of the optoelectronic arrangement 13 of FIG. 6. The light-emitting diode chip 100 of the optoelectronic arrangement 13 internally has a first diode structure 101, a second diode structure 102 and a third diode structure 103.

On its upper side 110, the light-emitting diode chip 100 of the optoelectronic arrangement 13 has a first upper-side electrical contact 141, a second upper-side electrical contact 142 and a third upper-side electrical contact 143. On a rear side opposite the upper side 110, the light-emitting diode chip 100 of the optoelectronic arrangement 13 has a rear-side electrical contact 140. The rear-side contact 140 electrically conductively connects to the first diode structure 101, the second diode structure 102 and the third diode structure 103. The first upper-side contact 141 is connected only to the first diode structure 101. The second upper-side contact 142 is connected only to the second diode structure 102. The third upper-side contact 143 is connected only to the third diode structure 103. The upper side contacts 141, 142, 143 therefore make it possible to drive the diode structures 101, 102, 103 of the light-emitting diode chip 100 of the optoelectronic arrangement 13 independently of one another.

The first diode structure 101 of the light-emitting diode chip 100 emits the two-dimensional pattern 210 of electromagnetic radiation 200 on the first sections 114 of the upper side 110 of the light-emitting diode chip 100. The second diode structure 102 of the light-emitting diode chip 100 of the optoelectronic arrangement 13 emits the second two-dimensional pattern 220 of electromagnetic radiation 200 on the second sections 115 of the upper side 110 of the light-emitting diode chip 100. The third diode structure 103 of the light-emitting diode chip 100 emits the third two-dimensional pattern 230 of electromagnetic radiation 200 on the third sections 116 of the upper side 110 of the light-emitting diode chip 100.

The optoelectronic arrangement 13 may, for example, be configured to emit the two-dimensional pattern 210, the second two-dimensional pattern 220 and the third two-dimensional pattern 230 of electromagnetic radiation 200 sequentially in time after one another.

It is possible to configure the light-emitting diode chip 100 of the optoelectronic arrangement 13 such that it can emit only two two-dimensional patterns 210, 220 or more than three two-dimensional patterns 210, 220, 230 of electromagnetic radiation 200.

FIG. 8 shows a schematic plan view of the upper side 110 of the light-emitting diode chip 100 of an optoelectronic arrangement 14 according to a fifth example. The optoelectronic arrangement 14 has great similarities with the optoelectronic arrangement 13 of FIG. 6. Only the differences between the optoelectronic arrangement 13 and the optoelectronic arrangement 14 are described below.

In the optoelectronic arrangement 14, the first sections 114, the second sections 115 and the third sections 116 of the upper side 110 of the light-emitting diode chip 100 respectively form two-dimensional point patterns. In the schematic representation of FIG. 8, only parts of the first sections 114, of the second sections 115 and of the third sections 116 of the upper side 110 of the light-emitting diode chip 100 are represented. The first sections 114, the second sections 115 and the third sections 116 are respectively configured to be disjointed, i.e. they do not overlap one another.

Since the first sections 114, the second sections 115 and the third sections 116 of the upper side 110 of the light-emitting diode chip 100 of the optoelectronic arrangement 14 are respectively configured as two-dimensional point patterns, the two-dimensional pattern 210 of electronic radiation 200 emitted on the first sections 114, the second two-dimensional pattern 220 of electromagnetic radiation 200 emitted on the second sections 115 and the third two-dimensional pattern 230 of electromagnetic radiation 200 emitted on the third sections 116 of the upper side 110 of the light-emitting diode chip 100 are also configured as two-dimensional point patterns.

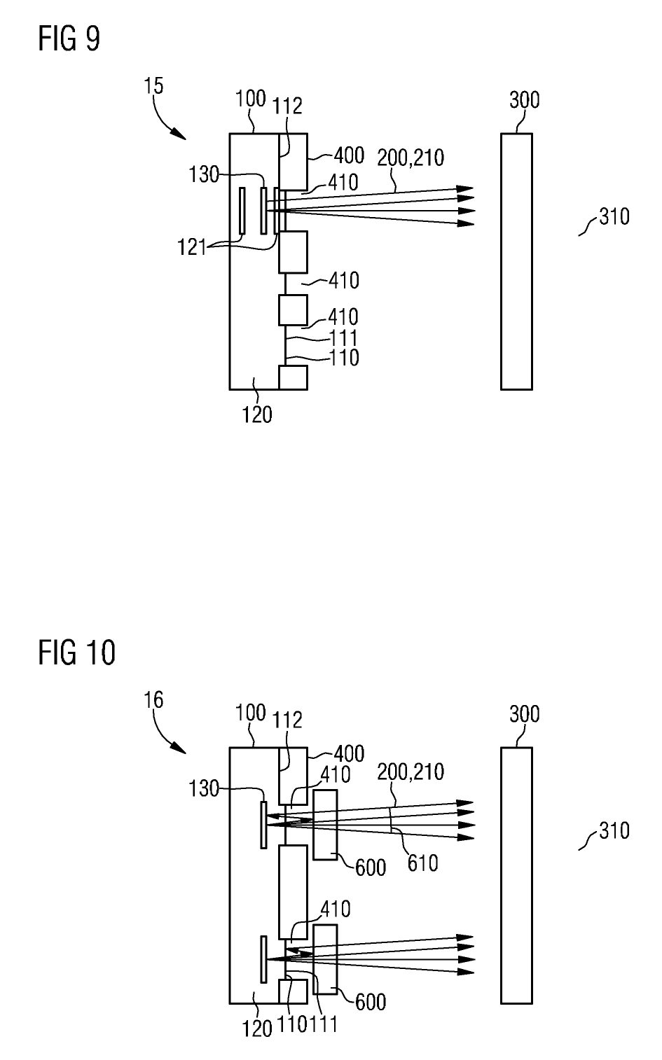

FIG. 9 shows a highly schematized sectional side view of an optoelectronic arrangement 15 according to a sixth example. The optoelectronic arrangement 15 has great similarities with the optoelectronic arrangement 11 of FIG. 3. Only the differences between the optoelectronic arrangement 11 of FIG. 3 and the optoelectronic arrangement 15 of FIG. 9 are described below. In other regards, the description of the optoelectronic arrangement 11 is also applicable for the optoelectronic arrangement 15.

In the optoelectronic arrangement 15, the light-emitting diode chip 100 is configured with an optical resonator 121. The optical resonator 121 may also be referred to as a resonant cavity. In this way, the electromagnetic radiation 200 emitted by the light-emitting diode chip 100 of the optoelectronic arrangement 15 can have wavelengths in a narrow spectral range. If the optoelectronic arrangement 15 is used in the depth measuring system 20, then the detector 30 of the depth measuring system 20 may have a narrowband filter which transmits only electromagnetic radiation in this narrow spectral range. In this way, the measurement quality in the depth measuring system 20 can be improved.

In another example of the optoelectronic arrangement, the light-emitting diode chip 100 may be configured to be operated in superluminescent mode, i.e. as a superluminescent diode. This can offer the advantage that the electromagnetic radiation 200 emitted by the light-emitting diode chip 100 on the radiation-emitting sections 111 of the upper side 110 of the light-emitting diode chip 100 is emitted in a narrow solid angle range about a direction perpendicular to the upper side 110 of the light-emitting diode chip 100.

FIG. 16 shows a highly schematized sectional side view of an optoelectronic arrangement 16 according to a seventh example. The optoelectronic arrangement 16 of FIG. 10 has great similarities with the optoelectronic arrangement 11 of FIG. 3. Only the differences between the optoelectronic arrangement 11 and the optoelectronic arrangement 16 will be described below. In other regards, the description of the optoelectronic arrangement 11 is also applicable for the optoelectronic arrangement 16.

In the optoelectronic arrangement 16, optical elements 600 are respectively arranged over the radiation-emitting sections 111 of the upper side 110 of the light-emitting diode chip 100. The optical elements 600 are configured to transmit only electromagnetic radiation 200 emitted in a fixed angle range 610 about a direction perpendicular to the upper side 110 of the light-emitting diode chip 100 of the optoelectronic arrangement 16. The angle range 610 may in this case be narrow.

Electromagnetic radiation 200 that strikes the optical element 600 at a larger angle is reflected by the optical element 600. Electromagnetic radiation reflected by the optical element 600 may, for example, be reabsorbed in the pn junction 130 of the light-emitting diode chip 100 and thereby reused (recycled), or it may be reflected again on the upper side 110 of the light-emitting diode chip 100 or on the aperture element 400 and thereby be given another opportunity to strike the optical element 600 within the angle range 610 and be transmitted through the optical element 600.

The effect of the optical elements 600 is that electromagnetic radiation is emitted by the optoelectronic arrangement 16 only in the angle range 610 about the direction perpendicular to the upper side 110 of the light-emitting diode chip 100.

It is possible for a separate optical element 600 to be arranged over each radiation-emitting section 111 of the upper side 110 of the light-emitting diode chip 100 of the optoelectronic arrangement 16. It is, however, also possible for an extended single optical element 600 to be provided, which extends over all the radiation-emitting sections 111 of the upper side 110 of the light-emitting diode chip 100.

The optical element 600 may, for example, be configured as a photonic crystal. As an alternative, the optical element 600 may also be formed from a transparent material having microstructuring, for example, structuring with microscale cone, prism or cylinder structures.

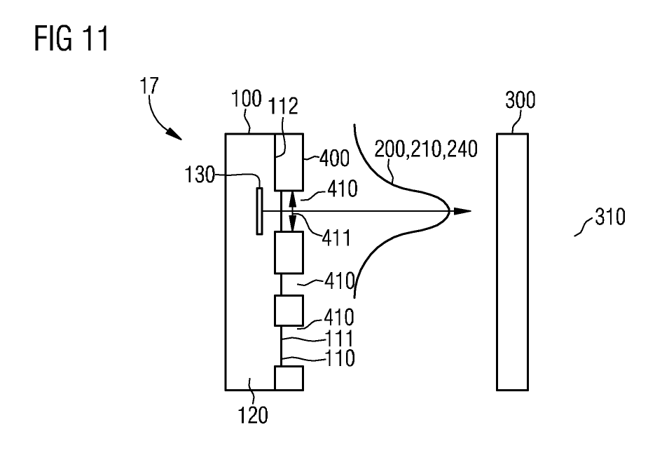

FIG. 11 shows a schematic sectional side view of an optoelectronic arrangement 17 according to an eighth example. The optoelectronic arrangement 17 has great similarities with the optoelectronic arrangement 11 of FIG. 3. Only the differences between the optoelectronic arrangement 17 and the optoelectronic arrangement 11 are described below.

In the optoelectronic arrangement 17, the openings 410 of the aperture element 400 have diameters 411 that may be dimensioned to be so small that only a fundamental mode 240 of the electromagnetic radiation 200 emitted by the light-emitting diode chip 100 of the optoelectronic arrangement 17 can pass through the openings 410 of the aperture element 400. To this end, the diameters 411 of the openings 410 of the aperture element 400 may, for example, be less than 10 μm.

The fundamental mode 240 of the electromagnetic radiation 200 has a defined narrow emission angle. Because the diameters 411 of the openings 410 of the aperture element 400 are dimensioned to be so small that only the fundamental mode 240 of the electromagnetic radiation 200 can pass the openings 410, the electromagnetic radiation 200 emitted through the openings 410 of the aperture element 400 by the optoelectronic arrangement 17 has a narrow emission angle centered around a direction perpendicular to the upper side 110 of the light-emitting diode chip 100 of the optoelectronic arrangement 17. In this way, the electromagnetic radiation 200 emitted by the optoelectronic arrangement 17 can be coupled simply and efficiently into the optically imaging element 300.

The aperture element 400 may have, instead of the openings 410 configured as holes, openings filled with a material whose refractive index differs from the refractive index of the surrounding aperture element 400.

The optoelectronic arrangements 13, 14, 15, 16, 17, described with the aid of FIGS. 6 to 11, may be used instead of the optoelectronic arrangement 10 in the depth measuring system 20 described with the aid of FIG. 5. The features, described with the aid of FIGS. 6 to 11, of the optoelectronic arrangements 13, 14, 15, 16, 17 may be combined with one another.

Our arrangements and systems have been illustrated and described in more detail with the aid of the preferred examples. This disclosure is not, however, restricted to the examples disclosed. Rather, other variants may be derived therefrom by those skilled in the art without departing from the protective scope of the appended claims.

This application claims priority of DE 10 2015 108 413.9 and DE 10 2015 122 627.8, the subject matter of which is incorporated herein by reference.

1.-20. (canceled)

21. An optoelectronic arrangement that produces a light pattern comprising:
a light-emitting diode chip configured to emit electromagnetic radiation on its upper side and forming a first two-dimensional pattern on the upper side of the light-emitting diode chip, and
an optically imaging element configured to project electromagnetic radiation emitted by the light-emitting diode chip into an environment of the optoelectronic arrangement.

22. The optoelectronic arrangement according to claim 21, wherein the first pattern is configured such that at least two radiation-emitting sections and two radiation-nonemitting sections alternate along a straight line arranged on the upper side of the light-emitting diode chip.

23. The optoelectronic arrangement according to claim 21, wherein the first pattern is a two-dimensional point pattern.

24. The optoelectronic arrangement according to claim 21, wherein the first pattern is a strip pattern.

25. The optoelectronic arrangement according to claim 21, wherein the light-emitting diode chip is configured to emit electromagnetic radiation with a wavelength in the infrared spectral range.

26. The optoelectronic arrangement according to claim 21, wherein
the light-emitting diode chip has an epitaxially grown layer sequence, and
a region of the layer sequence is structured according to the first pattern in the lateral direction.

27. The optoelectronic arrangement according to claim 26, wherein the layer sequence has a laterally structured pn junction.

28. The optoelectronic arrangement according to claim 21, wherein the optically imaging element comprises an optical lens.

29. The optoelectronic arrangement according to claim 21, wherein an aperture element having openings over radiation-emitting sections of the upper side is arranged over the upper side of the light-emitting diode chip.

30. The optoelectronic arrangement according to claim 29, wherein at least one of the openings is dimensioned to be so narrow that only a fundamental mode of the electromagnetic radiation can pass through the opening.

31. The optoelectronic arrangement according to claim 21, wherein a focusing element that at least partially parallelizes electromagnetic radiation emitted on the radiation-emitting section is arranged over at least one radiation-emitting section of the upper side of the light-emitting diode chip.

32. The optoelectronic arrangement according to claim 31, wherein the focusing element comprises a microprism.

33. The optoelectronic arrangement according to claim 21, wherein the light-emitting diode chip is configured to emit on its upper side electromagnetic radiation forming a second two-dimensional pattern different from the first pattern on the upper side of the light-emitting diode chip.

34. The optoelectronic arrangement according to claim 33, wherein the first pattern and the second pattern are configured such that the radiation-emitting sections of the upper side of the light-emitting diode chip forming the first pattern and the radiation-emitting sections of the upper side of the light-emitting diode chip forming the second pattern are disjointed.

35. The optoelectronic arrangement according to claim 33, wherein
the light-emitting diode chip has a multiplicity of electrical contacts, and
the light-emitting diode chip is configured to emit the first pattern or the second pattern depending on which electrical contact receives electrical current.

36. The optoelectronic arrangement according to claim 33, wherein the light-emitting diode chip is configured to emit on its upper side electromagnetic radiation forming a third two-dimensional pattern different from the first pattern and the second pattern on the upper side of the light-emitting diode chip.

37. The optoelectronic arrangement according to claim 21, wherein the light-emitting diode chip is configured with an optical resonator or as a superluminescent diode.

38. The optoelectronic arrangement according to claim 21, wherein an optical element that transmits only electromagnetic radiation emitted in a fixed angle range about a direction perpendicular to the upper side of the light-emitting diode chip is arranged over at least one radiation-emitting section of the upper side of the light-emitting diode chip.

39. The optoelectronic arrangement according to claim 38, wherein the optical element is configured as a photonic crystal.

40. A depth measuring system comprising the optoelectronic arrangement according to claim 21.
